(19) United States
(12) Patent Application Publication
(10) Pub. No.: US 2009/0302401 A1
(43) Pub. Date: Dec. 10, 2009

(54) PFET ENHANCEMENT DURING SMT

(75) Inventors: Lee Wee TEO, Singapore (SG); Jae Gon LEE, Singapore (SG); Shyue Seng TAN, Singapore (SG); Elgin QUEK, Singapore (SG)

Correspondence Address: HORIZON IP PTE LTD, 7500A Beach Road, #04-306/308 The Plaza, SINGAPORE 199591, SG

(73) Assignee: Chartered Semiconductor Manufacturing, Ltd., Singapore (SG)

(21) Appl. No.: 12/133,374

(22) Filed: Jun. 5, 2008

(51) Int. Cl. H01L 29/00; H01L 21/31

(52) U.S. Cl. 257/410; 438/776; 257/E29.001; 257/E21.24

(57) ABSTRACT

An integrated circuit having a substrate on which first and second active regions are defined. The first active region comprises a first transistor and the second active region comprises a second transistor having a first type stress. A barrier layer is provided over the substrate to reduce outdiffusion of dopants in the first active region.

### BACKGROUND

Transistor devices are commonly used in the integrated circuits. In light of increasing circuit density, mobility carrier enhancements became needed to maintain transistor performance, for example, enabling higher drive currents. Such mobility enhancements have traditionally been achieved with an application of appropriate stress to transistors. For example, tensile stress has been used to enhance electron mobility for a n-type field effect transistor (nFET) while compressive stress has been used to enhance hole mobility for a p-type field effect transistor (pFET).

Inducing the appropriate stress in the device may occur inherently or during process. An inherent inducement of stress may otherwise be known as intrinsic strain wherein the device substrate is inherently stressed, for example strained silicon on insulator (SOI) wafers. Process induced stress creates strain in one direction, i.e. uniaxial, in the direction of current flow. One common technique of implementing such process induced stress is known as stress memorization technique (SMT). Using SMT, stress is essentially memorized into the device with a deposition of an intrinsically stressed material such as silicon nitride over desired regions of the device, for example gate and/or source/drain (S/D) regions and dopant activation annealing followed by removal of the deposited intrinsically stressed material.

SMT commonly involves the use of, for example, nitride or oxide films to memorize tensile stress in nFETs. However, pFETs may be significantly degraded if the nitride film is not removed before the S/D dopant activation annealing due to excess boron out-diffusion.

In view of the foregoing, it is desirable to achieve desired nFET performance whilst improving the pFET performance during the SMT process.

### SUMMARY

Embodiments are generally related to semiconductor devices and their fabrication. In one embodiment, the application of appropriate stresses during the formation of transistors is described. The transistors can be incorporated into an integrated circuit (IC). In one embodiment, the IC comprises a substrate on which a first and a second active region is defined, the first active region comprises a first transistor and the second active region comprises a second transistor. The second transistor has a first type stress. The IC includes a barrier layer over the substrate to reduce outdiffusion of dopants in the first active region.

In accordance with another aspect, a method of forming an IC is provided. The method comprises providing a substrate on which a first and a second transistor is formed. A dielectric layer, disposed over the first and second transistors, is provided. A stress layer having a first and a second portion is provided over the dielectric layer. The first portion of the stress layer, disposed over the first transistor, is removed. A barrier layer is formed by performing treatment on the dielectric layer. The second portion of the stress layer, disposed over the second transistor, is processed; the process comprises memorizing a first type stress induced onto the second transistor.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention will now be described hereinafter, by way of example only with reference to the accompanying drawings, in which:

FIG. 1 shows an IC in accordance with one embodiment of the invention;

FIGS. 2a-f show a process for forming an IC in accordance with one embodiment of the invention;

FIGS. 3a-d show a process for forming an IC in accordance with another embodiment of the invention; and

FIG. 4 shows a process flow for forming an IC in accordance with one embodiment of the invention.

### DETAILED DESCRIPTION OF THE INVENTION

Embodiments generally relate to semiconductor devices. The semiconductor devices can be incorporated into ICs. The ICs can be any type of IC, for example dynamic or static random access memories, signal processors, or system on chip devices, mixed signal or analog devices such as A/D converters and switched capacitor filters. Other types of ICs are also useful. Such ICs are incorporated in various types of products, for example, computers and communication devices or systems such as phones and personal digital assistants (PDAs). Although embodiments are generally described in the context of semiconductor devices, other types of devices are also useful.

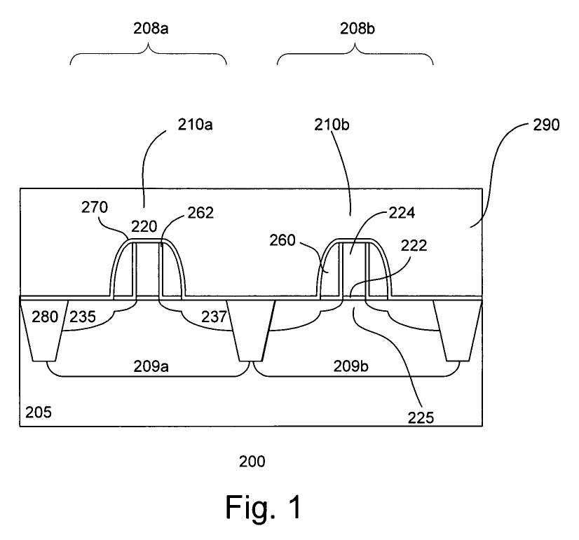

FIG. 1 shows a cross-sectional view of a portion of an IC 200 in accordance with one embodiment of the invention. The portion includes a substrate 205. The substrate comprises, for example, a silicon substrate. The silicon substrate is typically lightly doped with p-type dopants. Other types of substrates, such as silicon-on-insulator (SOI), silicon germanium, are also useful. The substrate is prepared with first and second active regions 208a-b. The active regions comprise heavily doped regions 209a-b with dopants of a first and a second polarity type, respectively. In one embodiment, the first polarity type comprises n-type and the second polarity type comprises p-type. For example, the first active region is a n-type doped well; the second active region is a p-type doped well. P-type dopants can include boron (B), aluminum or a combination thereof while n-type dopants can include phosphorus (P), arsenic (As), antimony (Sb) or a combination thereof. Isolating the active regions from each other and other device regions on the substrate are isolation regions 280. The isolation regions, for example, comprise STI regions. Other types of isolation regions are also useful.

The active regions comprise first and second transistors 210a-b. The first transistor comprises a p-type transistor on the n-type doped well and the second transistor comprises a n-type transistor on a p-type doped well. A transistor includes a gate or gate stack 220. The gate stack, for example, includes a gate electrode 224 over a gate dielectric 222. Typically, the gate electrode comprises polysilicon (doped or undoped) while the gate dielectric comprises silicon oxide. Other types of gate electrode or dielectric material are also useful.

The gate stack includes dielectric spacers on the gate sidewalls. The dielectric spacers comprise, for example, a dielectric material such as oxide and/or nitride. Other types of dielectric materials are also useful. In one embodiment, each dielectric spacer comprises a L-shaped silicon oxide liner 262 on which a silicon nitride spacer 260 is disposed. Other types of spacers or spacer designs are also useful.

First and second source/drain (SD) diffusion regions 235 and 237 are provided in the substrate adjacent to the gates. In one embodiment, a diffusion region includes a shallow SD extension portion and a deep SD portion. For p-type transistors, the diffusion regions comprise p-type dopants while n-type dopants are used for n-type transistors.

The gate of the n-type transistor in the second active region, in one embodiment, applies a tensile stress in a channel region 225 beneath the gate stack to improve carrier mobility of electrons, thereby improving performance of n-type transistors. In one embodiment, the gate applies the tensile stress using a stress memorization technique (SMT). SMT includes forming a sacrificial tensile stress dielectric layer, such as silicon nitride on the n-type transistor. The substrate is annealed, causing the gate electrode to retain the stress of the sacrificial stress dielectric layer.

Metal silicide contacts (not shown) can be provided on the surface of the diffusion regions and gate stack. The silicide contacts serve to reduce sheet resistance. Various types of metal silicide contacts can be used, such as nickel silicide contacts. Other type of metal silicide contacts can also be useful.

An etch stop layer (ESL) 270 is provided over the substrate covering the transistors. The ESL comprises, for example, silicon oxide or silicon oxynitride. Other types of dielectric materials may also be useful. In one embodiment, the ESL comprises a nitrogen containing ESL at least over the first active region. In another embodiment, the ESL comprises a nitrogen containing ESL over the first and second active regions. The nitrogen containing ESL layer serves as a barrier layer to prevent or reduce outdiffusion of p-type dopants, such as B from the diffusion regions. In one embodiment, the nitrogen containing ESL layer comprises a nitridated dielectric material such as silicon oxide or silicon oxynitride. Nitridation can be achieved by, for example, plasma nitridation or nitrogen implantation. The thickness of the nitrogen containing ESL, for example, is about 10-50 Å. Other thicknesses are also useful. In one embodiment, the nitrogen containing ESL comprises about 1-30% nitrogen.

A premetal dielectric (PMD) layer 290 is provided over the substrate, for example, on top of the etch stop layer. The PMD layer separates the substrate and transistor from a metal level. The PMD layer comprises, for example, silicon oxide. Other types of dielectric materials, such as TEOS and low-k dielectric materials, are also useful. Via plugs (not shown) are provided on the PMD layer which are coupled to metal lines of a metal layer (not shown) over the PMD layer. The plugs and metal lines form interconnections as desired.

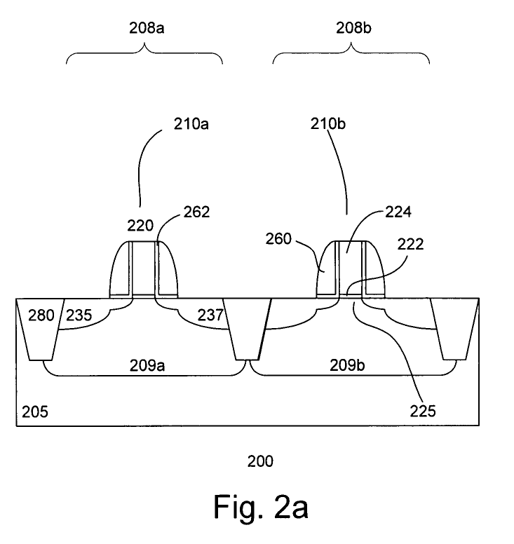

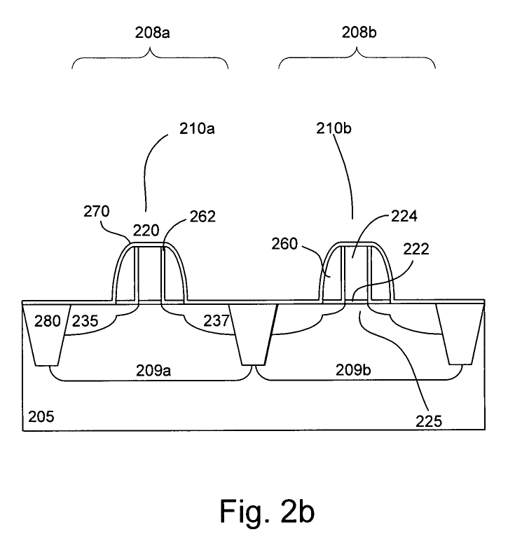

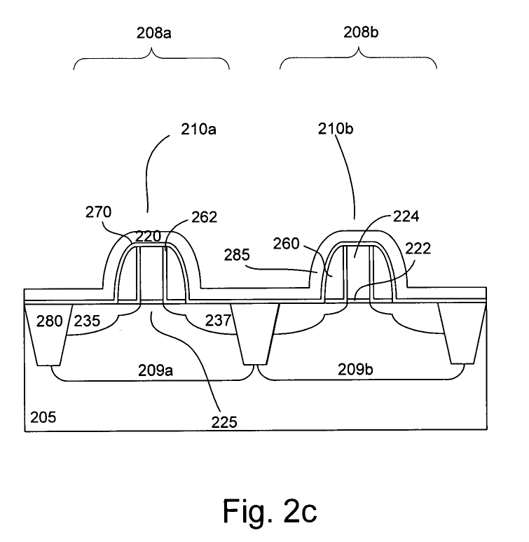

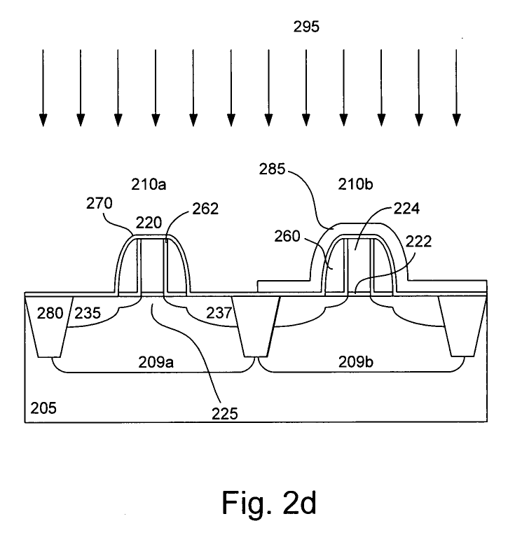

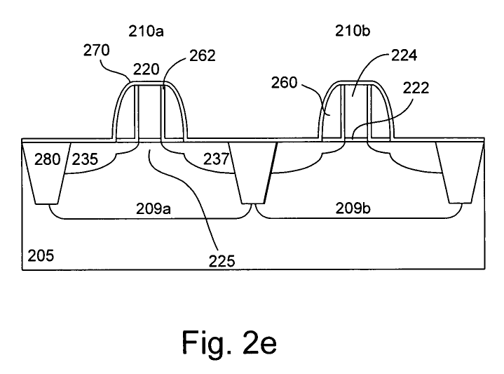

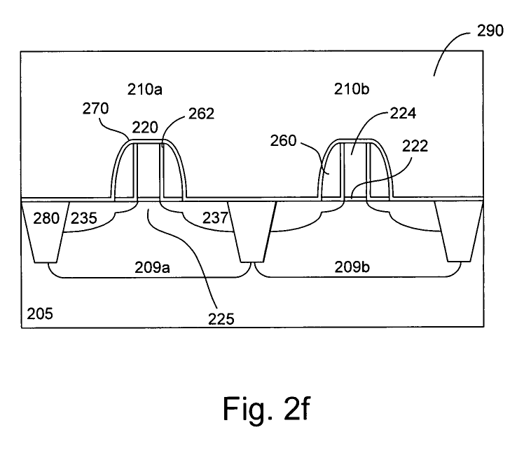

FIGS. 2a-f show cross-sectional views of a process for forming an IC 200 in accordance with one embodiment of the invention. Referring to FIG. 2a, a substrate 205 is provided. The substrate can comprise a silicon substrate, such as a lightly p-type doped substrate. Other types of substrates, including silicon-on-insulator (SOI) or silicon germanium, are also useful. The substrate is prepared with first and second active regions 208a-b. The active regions comprise a heavily doped regions 209a-b with dopants of a first and a second polarity type, respectively. In one embodiment, the first polarity type comprises n-type and the second polarity type comprises p-type. For example, the first active region is a n-type doped well; the second active region is a p-type doped well. P-type dopants can include boron (B), aluminum or a combination thereof while n-type dopants can include phosphorus (P), arsenic (As), antimony (Sb) or a combination thereof. To form the active regions, conventional ion implantation techniques, such as implantation with a mask can be used. Generally, the first and second types of active regions are formed in separate processes. Other techniques for forming the active regions are also useful.

The substrate is also prepared with isolation regions 280 to separate the active regions from each other and other active device regions. In one embodiment, the isolation regions comprise STIs. Various conventional processes can be employed to form the STI regions. For example, the substrate can be etched using conventional etch and mask techniques to form trenches which are then filled with dielectric material such as silicon oxide. Chemical mechanical polishing (CMP) can be performed to remove excess oxide and provide a planar substrate top surface. The STI regions can be formed, for example, prior to or after the formation of the doped wells. Other processes or materials can also be used to form the STIs. The STIs, for example, can include liners as well as filled with stress inducing dielectric materials. The stress inducing dielectric material can be a tensile stress inducing dielectric material such as silicon oxide or silicon nitride. Other dielectric materials are also useful.

Transistors 210a-b are prepared in the first and second active regions. In one embodiment, second type transistors are formed in the first active region and first type transistors are formed in the second active region. For example, a p-type transistor is formed in the n-type well and a n-type transistor is formed in the p-type well.

A transistor includes a gate or gate stack 220. The gate stack, for example, includes a gate electrode 224 over a gate dielectric 222. Typically, the gate electrode comprises polysilicon (doped or undoped) while the gate dielectric comprises silicon oxide. Other types of gate electrode or dielectric material are also useful. Conventional processes can be used to form the gate stacks of the transistors. For example, gate stack layers such as gate dielectric and gate electrode are sequentially formed on the substrate. The gate stack layers are patterned to form the gate stacks. To pattern the gate stack layers, mask and etch processes can be used. The gate stack layers can be patterned to form gate conductors. A gate conductor serves as a common gate for a plurality of transistors.

The gate stack includes dielectric spacers on the gate sidewalls. The dielectric spacers comprise, for example, a dielectric material such as oxide and/or nitride. Other types of dielectric materials are also useful. In one embodiment, each dielectric spacer comprises a L-shaped silicon oxide liner 262 on which a silicon nitride spacer 260 is disposed. Other types of spacers or spacer designs are also useful.

First and second source/drain (SD) diffusion regions 235 and 237 are provided in the substrate adjacent to the gates. The doped regions are formed by ion implantation. The implant can be self-aligned or formed using an implant mask. Other techniques for forming the diffusion regions are also useful. For p-type transistors, the diffusion regions comprise p-type dopants while n-type dopants are used for n-type transistors. The p-type and n-type diffusion regions are formed in separate implantation processes.

In one embodiment, a diffusion region includes a shallow SD extension portion and a deep SD portion. For example, shallow SD extension portions are formed after the gates are patterned and the deep SD portions are formed after spacer formation. After the formation of diffusion regions, the dopants are activated by, for example, a thermal annealing process. The annealing also serves to facilitate recovery from any deformation to the crystal structure incurred during the process of ion implantation. Typically, the anneal is carried out at 900-1100° C. Optionally, the dopants can be activated during a subsequent stress memorizing process (which will be described later).

Metal silicide contacts (not shown) can be provided on the surface of the diffusion regions and gate stack. The silicide contacts serve to reduce sheet resistance. Various types of metal silicide contacts can be used, such as nickel silicide contacts. Other types of metal silicide contacts can also be useful. To form metal silicide contacts, a metal layer is formed over the substrate. The metal layer is processed by annealing, causing a reaction with the silicon and metal to form metal silicide contacts in the diffusion region and gate electrode. In one embodiment, the substrate is annealed at a temperature of about 400-550° C. in N₂ ambient for about 5-120 sec. Other process parameters may also be useful. Untreated or excess metal are removed, leaving the metal silicide contacts.

Referring to FIG. 2b, the process continues by depositing an ESL 270 to cover the transistors and substrate. In one embodiment, the ESL comprises a dielectric material, for example, silicon oxide or silicon oxynitride. Various techniques, such as CVD, can be used to form the ESL. The ESL, in one embodiment, is subsequently processed to serve as a diffusion barrier for p-type dopants such as B.

In FIG. 2c, a dielectric stress layer 285 is formed on the substrate over the ESL. In one embodiment, the dielectric stress layer applies a tensile stress. The tensile stress, in one embodiment, is about 0.5-2 GPa. For example, the dielectric stress layer comprises silicon nitride formed by CVD. Other types of dielectric materials and deposition techniques are also useful. The stress layer, for example, is about 200-800 Å thick. Forming the stress layer with other thicknesses is also useful.

Referring to FIG. 2d, the tensile stress layer is patterned to remove portions over the first active region. In one embodiment, the stress layer is patterned to remove portions from the active region of the p-type transistor. A portion of the stress layer remains to cover the n-type transistor. To pattern the tensile stress layer, a photoresist or mask layer can be deposited on the substrate, covering the tensile stress layer. The photoresist layer can be patterned to expose portions of the tensile stress layer covering the first transistor 210a in the first active region. Conventional techniques, such as exposure and development, may then be used to pattern the photoresist layer. Following that, the patterned portion can be etched using traditional etch and mask techniques for removal of the desired part of the tensile stress layer.

In accordance with one embodiment of the invention, a treatment 295 is performed to impart barrier properties in the exposed portions of the ESL. The treatment, for example, comprises a nitridation process to provide nitrogen in the exposed portions of the ESL. In one embodiment, the treatment forms an oxynitride layer. Doping the ESL with nitrogen reduces outdiffusion of p-type atoms such as B from the p-type transistors. In one embodiment, the nitridation process comprises plasma nitridation. The nitridation, for example, can be a conventional decoupled plasma nitridation (DPN) process. The plasma nitridation may introduce nitrogen into the plasma via a nitrogen containing gas such as helicon. Alternatively, the nitridation process comprises nitrogen implantation. The nitrogen implantation can be performed, for example, at from 0.2 to a few kW for about 10 sec to a few mins.

The stress layer is processed, causing the second transistor to retain or “memorize” the stress of the stress layer. The stress memorizing process enhances carrier mobility, in one embodiment, for the n-type transistor. The stress memorizing process comprises, for example, a thermal annealing process. In one embodiment, the memorizing process also activates the dopants in the SD regions. By providing a nitridated ESL over the p-type diffusion regions of the substrate (for example active regions of p-type transistors), outdiffusion of p-type dopants such as B is reduced.

After the memorization process, the stress layer is removed, as shown in FIG. 2e. Removal of the stress layer can be achieved by a wet etch selective to the ESL. Other techniques for removing the stress layer are also useful. Removal of the stress layer over the p-type transistor avoids the negative impact of the tensile stress layer on tensile stress memorization of the gate of the p-type transistor.

As shown in FIG. 2f, a PMD layer 290 is deposited over the substrate. The PMD layer serves as an interlevel dielectric layer between the substrate and a metal layer above the PMD layer. The process continues by forming interconnections to the contacts of the transistors. For example, the PMD layer is patterned to create vias and trenches. The vias and trenches are then filled with conductive material, such as copper, to form interconnects. Additional processes are performed to complete the IC, for example, additional interconnect levels, final passivation, dicing, and packaging.

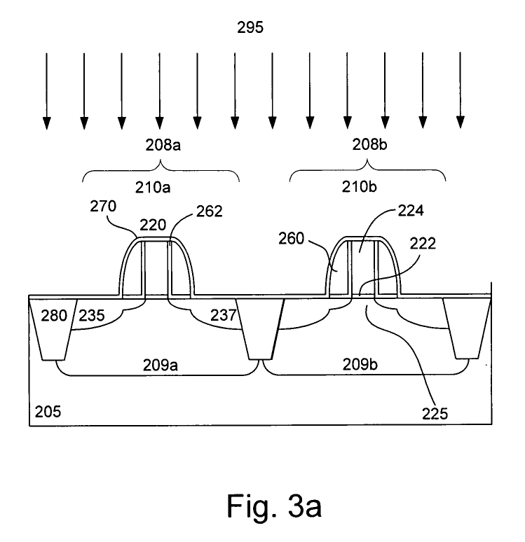

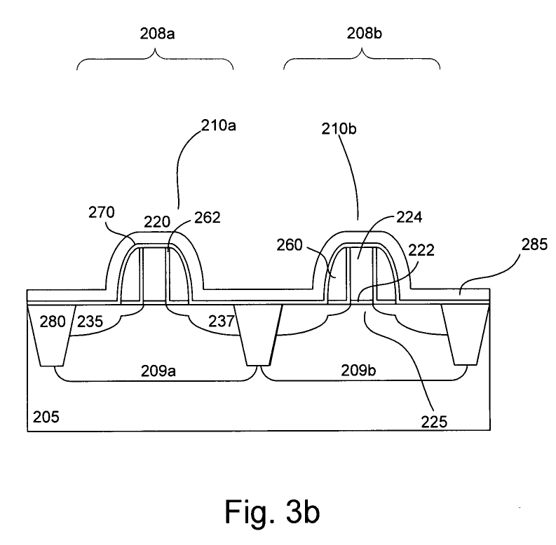

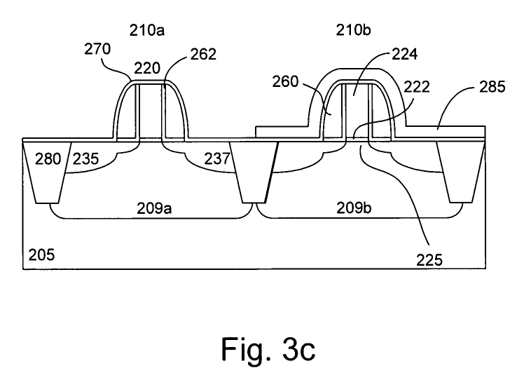

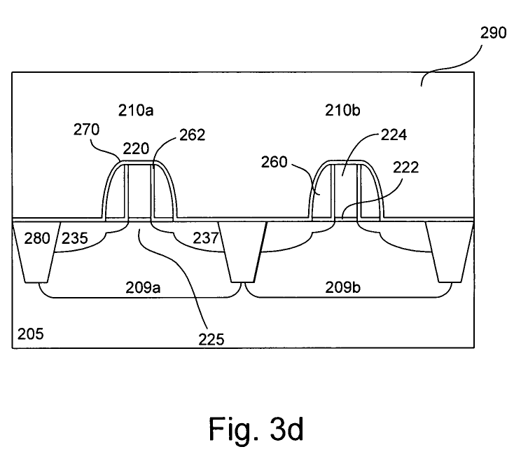

FIGS. 3a-d show an alternative process for forming an IC. Referring to FIG. 3a, a substrate 205 is provided. The substrate is prepared with first and second transistors 210a-b in first and second active regions 208a-b, as described in FIG. 2a. For example, a p-type transistor is formed in the n-type doped well 209a and a n-type transistor is formed in the p-type doped well 209b.

An ESL 270 is formed on the substrate. The ESL, in one embodiment, is subsequently processed to serve as a diffusion barrier for p-type dopants such as B. The ESL comprises, for example, silicon oxide or silicon oxynitride. Various techniques, such as CVD, can be used to form the ESL.

A treatment 295 is performed to impart barrier properties in ESL. The treatment, in one embodiment, comprises a nitridation process to provide nitrogen in the ESL. The nitridation process comprises, for example, plasma nitridation. Alternatively, the nitridation process comprises nitrogen implantation.

As shown in FIG. 3b, a dielectric stress layer 285 is formed on the substrate over the treated ESL. The dielectric stress layer applies a tensile stress in one embodiment of the invention. For example, the dielectric stress layer comprises silicon nitride formed by CVD. Other types of dielectric materials and deposition techniques are also useful. The stress layer, for example, can be about 200-800 Å thick. Forming the stress layer with other thicknesses is also useful.

In one embodiment, the stress layer is patterned to remove portions over the first active region, as shown in FIG. 3c. The remaining portion of the stress layer is processed, causing the second transistor to retain or “memorize” the stress of the stress layer. The stress memorizing process enhances carrier mobility in the n-type transistor. In one embodiment, the stress memorizing process comprises a thermal annealing process.

After the memorization process, the stress layer is removed, as shown in FIG. 3d. Removal of the stress layer can be achieved by a wet etch selective to the ESL. Other techniques for removing the stress layer are also useful. A PMD layer 290 is formed over the substrate, serving as an interlevel dielectric layer between the substrate and a metal layer above the PMD layer. The process continues by forming interconnections to the contacts of the transistors. For example, the PMD layer is patterned to create vias and trenches. The vias and trenches are then filled with conductive material, such as copper, to form interconnects. Additional processes are performed to complete the IC, for example, additional interconnect levels, final passivation, dicing, and packaging.

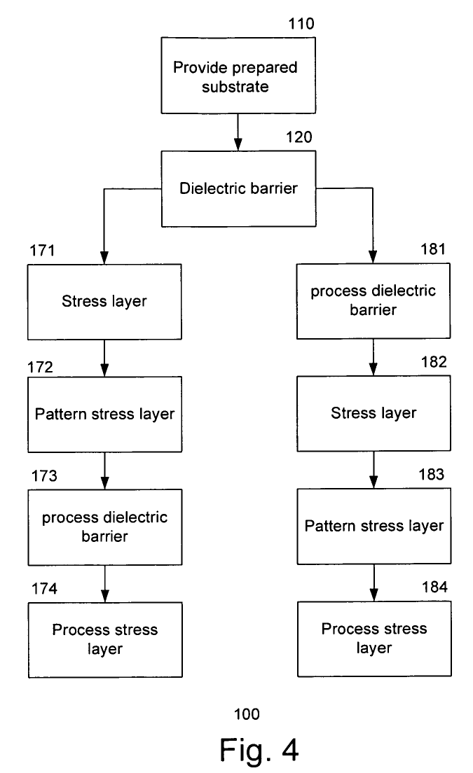

FIG. 4 shows a process flow 100 for forming an IC in accordance with one embodiment of the invention. At step 110, a substrate is provided. The substrate, in one embodiment, is prepared with first and second types of transistors in first and second active regions separated by isolation regions, such as STIs. In one embodiment, the first type transistor is a n-type transistor and the second type transistor is a p-type transistor. The transistors, for example, are FETs. Other types of transistors are also useful. A dielectric barrier layer is deposited on the prepared substrate at step 120. In one embodiment, the dielectric layer comprises silicon dioxide, silicon oxynitride or a combination thereof. Other types of dielectric materials are also useful.

In one embodiment, at step 171, a tensile stress layer is formed over the dielectric barrier. At step 172, part of the tensile stress layer is patterned to selectively remove it from the first transistor and leaving it over the second transistor. For example, the stress layer is removed from the first active region of the p-type transistor and remains over the second active region of the n-type transistor. Patterning of the stress layer can be performed by conventional mask and etch techniques.

At step 173, the exposed barrier layer is processed. The process, in one embodiment, comprises a nitridation process to provide nitrogen to the barrier layer. The nitridation process, in one embodiment, comprises plasma nitridation. Alternatively, the ntiridation process comprises a nitrogen implantation. After the barrier layer is processed, the stress layer is processed at step 174 to cause the gate of the second transistor to memorize the stress of the stress layer. The stress layer is removed after it is processed. The process continues to complete forming the IC.

In an alternative embodiment, after the dielectric barrier layer is formed at step 120, it is nitridated at step 181. The stress layer is then formed over the processed barrier layer at step 182. At step 183, the stress layer is patterned to remove it from the first transistor, leaving it over the second transistor. Thereafter, at step 184, the barrier layer is processed to cause the gate of the second transistor to memorize the stress of the stress layer. The stress layer is then removed and the process continues to complete forming the IC.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. An integrated circuit (IC) comprising:
a substrate on which a first and a second active region is defined, the first active region comprises a first transistor and the second active region comprises a second transistor, the second transistor having a first stress; and
a barrier layer over the substrate to reduce outdiffusion of dopants in the first active region.

2. The IC of claim 1 wherein the first active region comprises a doped region of a first polarity type and the second active region comprises a doped region of a second polarity type, the first and the second polarity types are opposing polarities.

3. The IC of claim 2 wherein the first polarity type is a n-type and the second polarity type is a p-type.

4. The IC of claim 1 wherein the second transistor comprises a gate stack and a channel region beneath the gate stack, the first stress is at the channel region.

5. The IC of claim 4 wherein the second transistor is a n-type transistor and the first stress at the channel region is a tensile stress.

6. The IC of claim 1 wherein the barrier layer is a nitrogen containing barrier layer.

7. A method of forming an integrated circuit (IC) comprising:
providing a substrate on which a first and a second transistor is formed;
providing a dielectric layer over the substrate, the dielectric layer covering the first and second transistors;
providing a stress layer over the dielectric layer, the stress layer having a first and a second portion;
removing the first portion of the stress layer;
performing treatment on the dielectric layer to form a barrier layer; and
processing the second portion of the stress layer.

8. The method of claim 7 wherein the treatment comprises a nitridation process to provide nitrogen in the dielectric layer.

9. The method of claim 8 wherein the treatment forms an oxynitride layer.

10. The method of claim 8 wherein the nitridation process comprises plasma nitridation.

11. The method of claim 8 wherein the nitridation process comprises nitrogen implantation.

12. The method of claim 7 wherein the stress layer comprises a first type stress, the first portion of the stress layer is disposed over the first transistor and the second portion of the stress layer is disposed over the second transistor.

13. The method of claim 12 wherein the processing of the second portion of the stress layer comprises memorizing the first type stress induced onto the second transistor.

14. The method of claim 13 wherein the second portion of the stress layer is removed after memorizing the first type stress induced onto the second transistor.

15. A method for forming an integrated circuit (IC) comprising:
providing a substrate having first and second active regions, the substrate comprises
a first transistor disposed on the substrate in the first active region,
a second transistor disposed on the substrate in the second active region,
a barrier layer disposed over the first and second transistors, the barrier layer reduces outdiffusion of dopants in the first active region,
a stress layer disposed over the barrier layer and the second transistor in the second active region; and
processing the stress layer to cause the second transistor to retain a first stress of the stress layer.

16. The method of claim 15 wherein the first active region comprises n-type doped well and the second active region comprises p-type doped well.

17. The method of claim 16 wherein the second transistor is a n-type transistor and the first stress is a tensile stress.

18. The method of claim 15 wherein the barrier layer is a nitrogen containing barrier layer.

19. The method of claim 18 wherein nitrogen is provided in the barrier layer by plasma nitridation or nitrogen implantation.

20. A method for forming an integrated circuit (IC) comprising:
providing a substrate prepared with a transistor;
providing a dielectric layer over the substrate covering the transistor; and
performing a treatment on the dielectric layer to form a barrier layer, wherein the barrier layer prevents outdiffusion of dopants during subsequent processing.
